(19) United States
(12) Patent Application Publication
(10) Pub. No.: US 2019/0112699 A1
(43) Pub. Date: Apr. 18, 2019

(54) VAPOR DEPOSITION MASK SUBSTRATE, VAPOR DEPOSITION MASK SUBSTRATE MANUFACTURING METHOD, VAPOR DEPOSITION MASK MANUFACTURING METHOD, AND DISPLAY DEVICE MANUFACTURING METHOD

(71) Applicant: TOPPAN PRINTING CO., LTD., Tokyo (JP)

(72) Inventor: Mikio SHINNO, Tokyo (JP)

(21) Appl. No.: 15/928,376

(22) Filed: Mar. 22, 2018

(30) Foreign Application Priority Data
Oct. 13, 2017 (JP) 2017-199921

(51) Int. Cl. C23C 14/04

(52) U.S. Cl. CPC C23C 14/042; H01L 51/0011

(57) ABSTRACT

A metal sheet has shapes in a width direction that are taken at different positions in a longitudinal direction of the metal sheet and differ from one another. Each shape includes undulations repeating in the width direction. Each undulation includes a valley at each of two ends of the undulation. Each undulation has a length, which is a length of a straight line in the width direction that connects one of the valleys of the undulation to the other valley. A percentage of a height of each undulation relative to the length of the undulation is a unit steepness. The metal sheet has a unit length in the longitudinal direction of 500 mm. A maximum value of the unit steepnesses of the metal sheet per the unit length is a first steepness. The first steepness is less than or equal to 0.5%.

### BACKGROUND

The present invention relates to a vapor deposition mask substrate, a method for manufacturing a vapor deposition mask substrate, a method for manufacturing a vapor deposition mask, and a method for manufacturing a display device.

A vapor deposition mask includes a first surface, a second surface, and holes extending through the first and second surfaces. The first surface faces a target such as a substrate, and the second surface is opposite to the first surface. The holes each include a first opening, which is located in the first surface, and a second opening, which is located in the second surface. The vapor deposition material entering the holes through the second openings forms on the target a pattern corresponding to the position and shape of the first openings (see Japanese Laid-Open Patent Publication No. 2015-055007, for example).

Each hole of the vapor deposition mask has a cross-sectional area that increases from the first opening toward the second opening. This increases the amount of vapor deposition material entering the hole through the second opening so that an adequate amount of vapor deposition material reaches the first opening. However, at least some of the vapor deposition material entering the hole through the second opening adheres to the wall surface defining the hole, failing to reach the first opening. The vapor deposition material adhering to the wall surface may prevent other vapor deposition material from passing through the hole, lowering the dimensional accuracy of the pattern.

To reduce the volume of vapor deposition material adhering to the wall surfaces, a structure has been contemplated in which the thickness of the vapor deposition mask is reduced to reduce the areas of the wall surfaces. In order to reduce the thickness of the vapor deposition mask, a technique has been contemplated that reduces the thickness of the metal sheet used as the substrate for manufacturing the vapor deposition mask.

However, in the process of etching the metal sheet to form holes, a smaller thickness of the metal sheet results in a smaller volume of metal to be removed. This narrows the permissible ranges in the processing conditions, such as the duration for which etchant is supplied to the metal sheet and the temperature of the supplied etchant. This increases the difficulty in achieving the required dimensional accuracy of the first and second openings. In particular, the manufacturing of metal sheet involves a rolling step, in which the base material is drawn with rolls, or an electrolysis step, in which the metal sheet deposited on an electrode is peeled off from the electrode. Accordingly, the metal sheet has an undulated shape. In the metal sheet having such a shape, the duration for which the ridges in the undulated shape are in contact with the etchant differs greatly from that of the valleys in the undulated shape. This aggravates the reduced accuracy resulting from the narrowed permissible ranges described above. As such, although a thinner vapor deposition mask reduces the amount of vapor deposition material adhering to the wall surfaces and thereby increases the dimensional accuracy of the patterns in repeated vapor deposition, such a vapor deposition mask involves another problem that the required dimensional accuracy of the pattern in each vapor deposition is difficult to achieve.

### SUMMARY OF THE INVENTION

It is an objective of the present invention to provide a vapor deposition mask substrate, a method for manufacturing a vapor deposition mask substrate, a method for manufacturing a vapor deposition mask, and a method for manufacturing a display device that increase the accuracy of the patterns formed by vapor deposition.

In accordance with one aspect of the present disclosure, a vapor deposition mask substrate is provided, which is a metal sheet that has a shape of a strip and is configured to be etched to include a plurality of holes and used to manufacture a vapor deposition mask. The metal sheet has a longitudinal direction and a width direction. The metal sheet has shapes in the width direction that are taken at different positions in the longitudinal direction of the metal sheet and differ from one another. Each shape includes undulations repeating in the width direction. Each undulation includes a valley at each of two ends of the undulation. Each undulation has a length, which is a length of a straight line in the width direction that connects one of the valleys of the undulation to the other valley. A percentage of a height of each undulation relative to the length of the undulation is a unit steepness. The metal sheet has a unit length in the longitudinal direction of 500 mm. A maximum value of the unit steepnesses of the metal sheet per the unit length is a first steepness. The first steepness is less than or equal to 0.5%.

In accordance with another aspect of the present disclosure, a method for manufacturing a vapor deposition mask substrate is provided. The vapor deposition mask substrate is a metal sheet that has a shape of a strip and is configured to be etched to include a plurality of holes and used to manufacture a vapor deposition mask. The method includes obtaining the metal sheet by rolling a base material. The metal sheet has a longitudinal direction and a width direction. The metal sheet has shapes in the width direction that are taken at different positions in the longitudinal direction of the metal sheet and differ from one another. Each shape includes undulations repeating in the width direction. Each undulation includes a valley at each of two ends of the undulation. Each undulation has a length, which is a length of a straight line in the width direction that connects one of the valleys of the undulation to the other valley. A percentage of a height of each undulation relative to the length of the undulation is a unit steepness. The metal sheet has a unit length in the longitudinal direction of 500 mm. A maximum value of the unit steepnesses of the metal sheet per the unit length is a first steepness. The base material is rolled such that the first steepness is less than or equal to 0.5%.

In accordance with a further aspect of the present disclosure, a method for manufacturing a vapor deposition mask is provided. The method includes forming a resist layer on a metal sheet having a shape of a strip and forming a plurality of holes in the metal sheet by etching using the resist layer as a mask to form a mask portion. The metal sheet has a longitudinal direction and a width direction. The metal sheet has shapes in the width direction that are taken at different positions in the longitudinal direction of the metal sheet and differ from one another. Each shape includes undulations repeating in the width direction. Each undulation includes a valley at each of two ends of the undulation. Each undulation has a length, which is a length of a straight line in the width direction that connects one of the valleys of the undulation to the other valley. A percentage of a height of each undulation relative to the length of the undulation is a unit steepness. The metal sheet has a unit length in the longitudinal direction of 500 mm. A maximum value of the unit steepnesses of the metal sheet per the unit length is a first steepness. The first steepness is less than or equal to 0.5%.

In accordance with yet another aspect of the present disclosure, a method for manufacturing a display device is provided. The method includes preparing a vapor deposition mask manufactured by the above-described method for manufacturing a vapor deposition mask and forming a pattern by vapor deposition using the vapor deposition mask.

### BRIEF DESCRIPTION OF THE DRAWINGS

The features of the present invention that are believed to be novel are set forth with particularity in the appended claims. The invention, together with objects and advantages thereof, may best be understood by reference to the following description of the presently preferred embodiments together with the accompanying drawings in which:

FIG. 1 is a perspective view showing a vapor deposition mask substrate.

FIG. 2 is a plan view showing a measurement substrate.

FIG. 3 is a diagram showing a graph for illustrating steepness together with the cross-sectional structure of a measurement substrate.

FIG. 4 is a plan view showing the planar structure of a mask device.

FIG. 5 is a partial cross-sectional view showing an example of the cross-sectional structure of a mask portion.

FIG. 6 is a partial cross-sectional view showing another example of the cross-sectional structure of a mask portion.

FIG. 7 is a partial cross-sectional view showing an example of the structure of joining between an edge of a mask portion and a frame portion.

FIG. 8 is a partial cross-sectional view showing another example of the structure of joining between an edge of a mask portion and a frame portion.

FIG. 9A is a plan view showing an example of the planar structure of a vapor deposition mask.

FIG. 9B is a cross-sectional view showing an example of the cross-sectional structure of the vapor deposition mask.

FIG. 10A is a plan view showing another example of the planar structure of a vapor deposition mask.

FIG. 10B is a cross-sectional view showing another example of the cross-sectional structure of the vapor deposition mask.

FIG. 11 is a process diagram showing a rolling step for manufacturing a vapor deposition mask substrate.

FIG. 12 is a process diagram showing a heating step for manufacturing a vapor deposition mask substrate.

FIGS. 13 to 18 are process diagrams showing an etching step for manufacturing a mask portion.

FIGS. 19A to 19H are process diagrams for illustrating an example of a method for manufacturing a vapor deposition mask.

FIGS. 20A to 20E are process diagrams for illustrating an example of a method for manufacturing a vapor deposition mask.

FIGS. 21A to 21F are process diagrams for illustrating an example of a method for manufacturing a vapor deposition mask.

FIG. 22 is a plan view showing the planar structure of a measurement substrate of an example together with dimensions.

### DESCRIPTION OF THE PREFERRED EMBODIMENTS

Referring to FIGS. 1 to 22, embodiments of a vapor deposition mask substrate, a method for manufacturing a vapor deposition mask substrate, a method for manufacturing a vapor deposition mask, and a method for manufacturing a display device are now described.

[Structure of Vapor Deposition Mask Substrate]

As shown in FIG. 1, a vapor deposition mask substrate 1 is a metal sheet having the shape of a strip. The vapor deposition mask substrate 1 has an undulated shape in which undulations are repeated in the width direction DW at each of different positions in the longitudinal direction DL. The undulated shapes at different positions in the longitudinal direction DL of the vapor deposition mask substrate 1 differ from one another. The different undulated shapes differ in characteristics such as the number of undulations (protrusions and depressions), the length of undulation, and the height of undulations in the undulated shapes. For illustrative purposes, the shapes of the vapor deposition mask substrate 1 are exaggerated in FIG. 1. The thickness of the vapor deposition mask substrate 1 is between 10 μm and 50 μm inclusive. The uniformity in thickness of the vapor deposition mask substrate 1 is such that the ratio of the difference between the maximum thickness and the minimum thickness to the average thickness is less than or equal to 5%, for example.

The vapor deposition mask substrate 1 may be made of nickel or a nickel-iron alloy, such as a nickel-iron alloy containing at least 30 mass % of nickel. In particular, the vapor deposition mask substrate 1 may be made of Invar, which is mainly composed of an alloy containing 36 mass % of nickel and 64 mass % of iron. When the main component is the alloy of 36 mass % of nickel and 64 mass % of iron, the remainder contains additives such as chromium, manganese, carbon, and cobalt. When the vapor deposition mask substrate 1 is made of Invar, the vapor deposition mask substrate 1 has a thermal expansion coefficient of about 1.2×10⁻⁶/° C. The vapor deposition mask substrate 1 having such a thermal expansion coefficient produces a mask that changes its size due to thermal expansion to an extent equivalent to that of a glass substrate and a polyimide sheet. Thus, a glass substrate or a polyimide sheet is suitably used as a vapor deposition target.

[Steepness]

When the vapor deposition mask substrate 1 is placed on a level surface, the position (height) of the surface of the vapor deposition mask substrate 1 with respect to the level surface is referred to as the surface position.

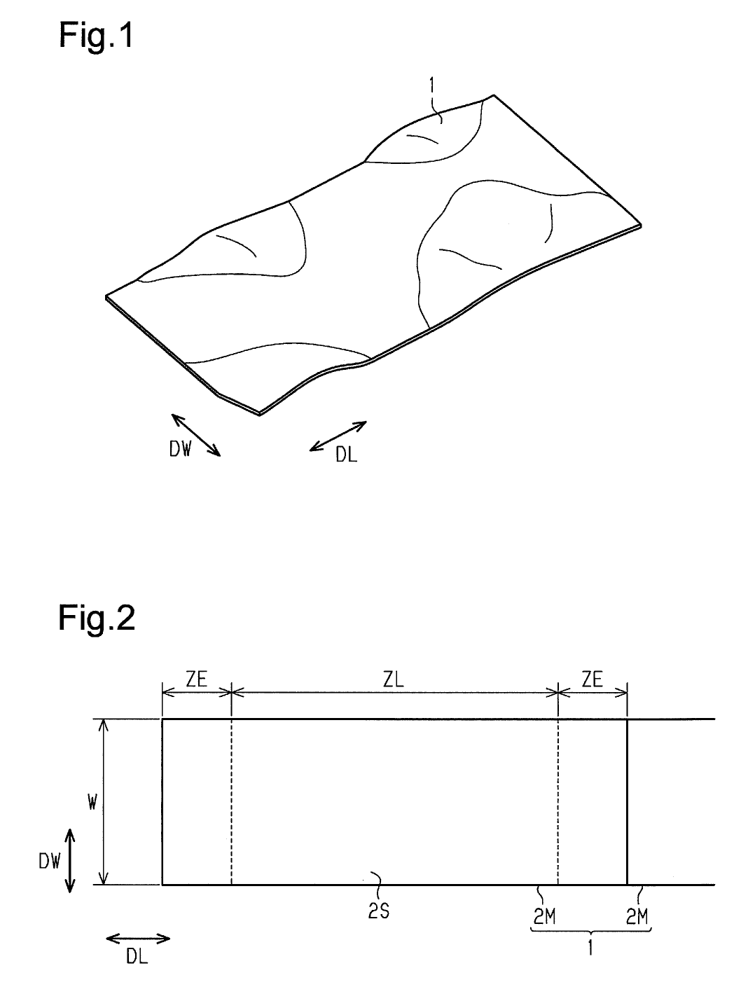

Referring to FIG. 2, to measure the surface position, a metal sheet, which is manufactured through rolling or electrolysis, is cut such that the dimension of the metal sheet in the width direction DW is a width W. Then, the vapor deposition mask substrate 1, which is a metal sheet having the shape of a strip, is wound to form a roll. Then, a slitting step is performed in which the vapor deposition mask substrate 1 is cut across in the width direction DW (cut across the width) so that a measurement substrate 2M is cut out as a section of the vapor deposition mask substrate 1 in the longitudinal direction DL. The width W in the width direction DW of the measurement substrate 2M is equal to the dimension in the width direction DW of the vapor deposition mask substrate 1. Then, the surface position of the surface 2S of the measurement substrate 2M is measured at different positions in the width direction DW and at predetermined intervals in the longitudinal direction DL. The area in which the surface position is measured is a measurement area ZL.

The measurement area ZL is an area that excludes the non-measurement areas ZE located at the two edges in the longitudinal direction DL of the measurement substrate 2M. The measurement area ZL also excludes the non-measurement areas (not shown) located at the two edges in the width direction DW of the measurement substrate 2M. The slitting step for cutting the vapor deposition mask substrate 1 may give the measurement substrate a new undulated shape that differs from the undulated shape of the vapor deposition mask substrate 1. The length in the longitudinal direction DL of each non-measurement area ZE corresponds to the area in which such a new undulated shape can be formed, and the non-measurement areas ZE are excluded from the measurement of surface positions. The length in the longitudinal direction DL of each non-measurement area ZE is 100 mm, for example. To exclude the new undulated shape formed in the slitting step at the edges in the width direction DW, each of the non-measurement areas at the edges in the width direction DW has a dimension of 10 mm, for example, in the width direction DW from the edge.

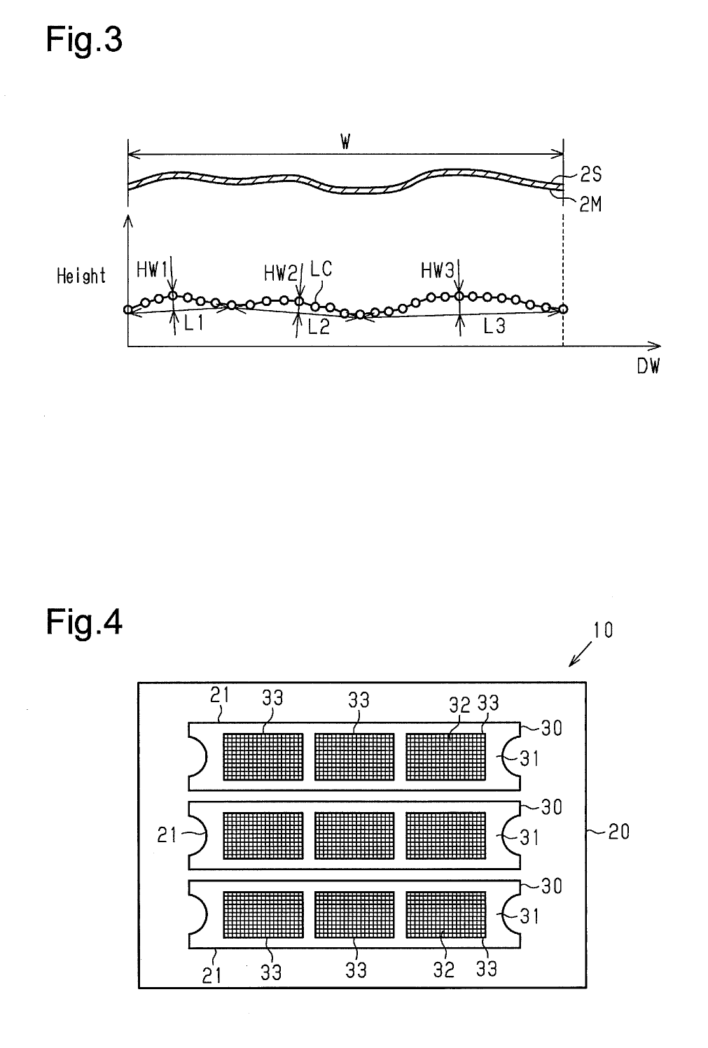

FIG. 3 is a graph showing an example of the surface positions at different positions in the width direction DW of the measurement substrate 2M, together with the cross-sectional structure of a cross-section taken in the width direction DW of the measurement substrate 2M. FIG. 3 shows an example of one of the different sections in the longitudinal direction DL. This section has three undulations in the width direction DW.

As shown in FIG. 3, the different positions in the width direction DW at which surface positions are measured are set at intervals that enable representation of the undulated shape of the vapor deposition mask substrate 1. The different positions in the width direction DW at which surface positions are measured are at intervals of between 1 mm and 20 mm inclusive in the width direction DW, for example. The line LC connecting the surface positions at different positions in the width direction DW is considered as a line extending along the surface of the vapor deposition mask substrate 1. The length of the line LC is the distance along the surface of the vapor deposition mask substrate 1. The undulations in the line LC each have a length L1, L2 or L3, which is the length of the straight line connecting one of the valleys of the undulation to the other in the width direction DW. The undulations in the line LC each have a height HW1, HW2 or HW3, which is the height from the straight line connecting one of the valleys of the undulation to the other. A unit steepness of the vapor deposition mask substrate 1 is the percentage of the height of an undulation relative to the length of the undulation. In the example in FIG. 3, the unit steepnesses are the height HW1/length L1×100 (%), the height HW2/length L2×100 (%), and the height HW3/length L3×100 (%). When the peak of an undulation is located at an edge in the width direction DW, the length in the width direction DW of the undulation is estimated to be twice the length from the peak to the valley of the undulation.

The vapor deposition mask substrate 1 has a unit length in the longitudinal direction DL of 500 mm.

The vapor deposition mask substrate 1 has a first steepness, which is the maximum value of the unit steepnesses of all the undulations in a section having the unit length and the width W in the vapor deposition mask substrate 1.

The vapor deposition mask substrate 1 also has a second steepness, which is the maximum value of the unit steepnesses of all the undulations in the width direction DW at a position in the longitudinal direction DL. That is, the first steepness of the vapor deposition mask substrate 1 is the maximum value of the second steepnesses per unit length.

The number of undulations in the width direction DW at a position in the longitudinal direction DL of the vapor deposition mask substrate 1 is referred to as an undulation quantity at the position.

The first steepness of the vapor deposition mask substrate 1 satisfies Condition 1 below. As for the steepnesses in the width direction DW of the vapor deposition mask substrate 1, it is preferable that the second steepnesses satisfy Condition 2 and the undulation quantities satisfy Conditions 3 and 4.

[Condition 1] The first steepness is less than or equal to 0.5%.

[Condition 2] The average value of the second steepnesses is less than or equal to 0.25%.

[Condition 3] The maximum value of the undulation quantities per unit length is less than or equal to four.

[Condition 4] The average value of undulation quantities per unit length is less than or equal to two.

In the vapor deposition mask substrate 1 that satisfies Condition 1, the maximum value of unit steepnesses, which are steepnesses in the width direction DW, is less than or equal to 0.5%. Accordingly, the vapor deposition mask substrate 1 is free of an undulation having a steep protrusion or depression as viewed in the longitudinal direction DL. A steep protrusion or depression tends to cause stagnation of the liquid supplied to the protrusion or depression. The presence or absence of such an undulation is not readily identifiable from the average value of unit steepnesses, for example. Thus, when the liquid for processing is supplied to the surface of the vapor deposition mask substrate 1, which is transferred in the longitudinal direction DL, the liquid will not be stagnated around the protruding undulations. This facilitates the uniform flow of liquid on the surface of the vapor deposition mask substrate 1 even when the same process is repeated in the longitudinal direction DL. Accordingly, the liquid supplied to the surface of the vapor deposition mask substrate is unlikely to stagnate in a section in the longitudinal direction DL. This increases the uniformity of processing including treatment using a liquid such as etchant in the longitudinal direction DL, that is, the uniformity of the holes in the vapor deposition mask substrate 1 in the longitudinal direction DL. This, in turn, increases the accuracy of the pattern formed by vapor deposition.

Further, in roll-to-roll processing, where the vapor deposition mask substrate 1 is pulled out of a roll and then transferred, the tension that pulls the vapor deposition mask substrate 1 acts in the longitudinal direction DL of the vapor deposition mask substrate 1. The tension acting in the longitudinal direction DL stretches the warpage and depressions in the vapor deposition mask substrate 1 in the longitudinal direction DL. Such tension first acts on the section of the vapor deposition mask substrate 1 that is about to be pulled out of the roll. In this section, a greater steepness in the width direction DW increases variation in the degrees of stretching. Each time the roll is rotated, the time when the tension is likely to cause stretching and the time when the tension is unlikely to cause stretching are repeated. This results in problems such as deviations in transfer and creases of the vapor deposition mask substrate 1, which is transferred in the longitudinal direction DL. As such, larger steepnesses in the width direction DW tend to cause deviations in transfer in the roll-to-roll processing. In addition, when attaching another film such as dry film resist to the vapor deposition mask substrate 1, larger steepnesses tend to cause problems such as misalignment and reduced adhesion resulting from creases. The structure satisfying Condition 1 limits deviations in transfer, misalignment, and creases, thereby improving the accuracy of the patterns formed by vapor deposition.

The liquid supplied to the surface of the vapor deposition mask substrate 1 may be developing solution for developing the resist layer on the surface of the vapor deposition mask substrate 1 and cleaning solution for removing the developing solution from the surface. The liquid supplied to the surface of the vapor deposition mask substrate 1 may also be etchant for etching the vapor deposition mask substrate 1 and cleaning solution for removing the etchant from the surface. Further, the liquid supplied to the surface of the vapor deposition mask substrate 1 may be stripping solution for stripping the resist layer remaining on the surface of the vapor deposition mask substrate 1 after etching, and cleaning solution for removing the stripping solution from the surface.

The structure described above, in which the flow of liquid supplied to the surface of the vapor deposition mask substrate 1 is unlikely to stagnate in the longitudinal direction DL, increases the uniformity of the processing using liquid on the surface of the vapor deposition mask substrate 1. In addition, the structure in which the average value of the second steepness satisfies Condition 2 limits the unit steepness over the entire length in the longitudinal direction DL, further increasing the accuracy of the patterns. Moreover, this structure improves the adhesion between the vapor deposition mask substrate 1, which is transferred in the longitudinal direction DL, and the resist layer, such as dry film, and the accuracy of exposure to the resist layer. That is, the structure that satisfies Conditions 1 and 2 improves the accuracy of exposure, in addition to limiting stagnation of the liquid flow in the longitudinal direction DL. This further improves the uniformity of processing.

Further, in the vapor deposition mask substrate 1 that satisfies Condition 3, the maximum value of undulation quantities per unit length is less than or equal to four. Accordingly, the vapor deposition mask substrate 1 does not have many undulations as viewed in the longitudinal direction DL. Thus, when liquid for processing is supplied to the surface of the vapor deposition mask substrate 1, which is transferred in the longitudinal direction DL, the liquid will not stagnate, which would occur if a section in the longitudinal direction DL has a large undulation quantity. This facilitates the uniform flow of liquid on the surface of the vapor deposition mask substrate 1 even when the same process is repeated in the longitudinal direction DL.

Furthermore, in the vapor deposition mask substrate 1 that satisfies Condition 4, the average value of undulation quantities per unit length is less than or equal to two, such that the number of undulations is not large over the entire length in the longitudinal direction DL. Accordingly, this structure further improves the adhesion between the vapor deposition mask substrate 1, which is transferred in the longitudinal direction DL, and the resist layer, such as dry film, and increases the accuracy of exposure to the resist layer.

As such, the structures satisfying Conditions 1 to 4 and the advantages of these structures are achievable only by identifying the problem in surface processing using liquid that occurs in the vapor deposition mask substrate 1 transferred in the longitudinal direction DL, as well as the problem associated with the effect of the tension acting in the longitudinal direction DL.

[Structure of Mask Device]

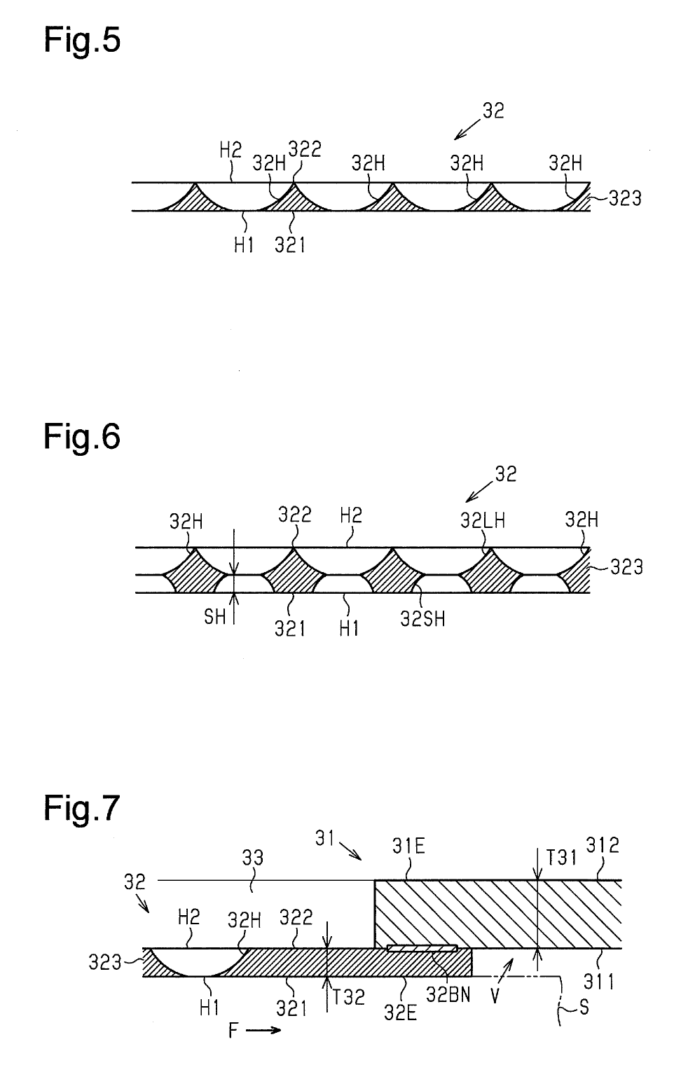

FIG. 4 schematically shows the planar structure of a mask device including a vapor deposition mask manufactured using the vapor deposition mask substrate 1. FIG. 5 shows an example of the cross-sectional structure of a mask portion of a vapor deposition mask. FIG. 6 shows another example of the cross-sectional structure of a mask portion of a vapor deposition mask. The number of the vapor deposition masks in the mask device and the number of mask portions in a vapor deposition mask 30 shown are by way of example.

As shown in FIG. 4, a mask device 10 includes a main frame 20 and three vapor deposition masks 30. The main frame 20 has the shape of a rectangular frame and supports the vapor deposition masks 30. The main frame 20 is attached to a vapor deposition apparatus that performs vapor deposition. The main frame 20 includes main frame holes 21, which extend through the main frame 20 and extend substantially over the entire areas in which the vapor deposition masks 30 are placed.

The vapor deposition masks 30 include a plurality of frame portions 31, each having the shape of a planar strip, and three mask portions 32 in each frame portion 31. Each frame portion 31, which supports mask portions 32 and has the shape of a planar strip, is attached to the main frame 20. Each frame portion 31 includes frame holes 33, which extend through the frame portion 31 and extend substantially over the entire areas in which mask portions 32 are placed. The frame portion 31 has a higher rigidity than the mask portions 32 and is shaped as a frame surrounding the frame holes 33. The mask portions 32 are separately fixed by welding or adhesion to the frame inner edge sections of the frame portion 31 defining the frame holes 33.

As shown in FIG. 5, an example of a mask portion 32 is made of a mask plate 323. The mask plate 323 may be a single planar member made of a vapor deposition mask substrate 1 or a laminate of a single planar member made of a vapor deposition mask substrate 1 and a plastic sheet. FIG. 5 shows a single planar member made of the vapor deposition mask substrate 1.

The mask plate 323 includes a first surface 321 (the lower surface in FIG. 5) and a second surface 322 (the upper surface in FIG. 5), which is opposite to the first surface 321. The first surface 321 faces the vapor deposition target, such as a glass substrate, when the mask device 10 is attached to a vapor deposition apparatus. The second surface 322 faces the vapor deposition source of the vapor deposition apparatus. The mask portion 32 includes a plurality of holes 32H extending through the mask plate 323. The wall surface defining each hole 32H is inclined with respect to the thickness direction of the mask plate 323 in a cross-sectional view. In a cross-sectional view, the wall surface defining each hole 32H may have a semicircular shape protruding outward of the hole 32H as shown in FIG. 5, or a complex curved shape having a plurality of bend points.

The mask plate 323 has a thickness of between 1 μm and 50 μm inclusive, preferably between 2 μm and 20 μm inclusive. The thickness of the mask plate 323 that is less than or equal to 50 μm allows the holes 32H formed in the mask plate 323 to have a depth of less than or equal to 50 μm. This thin mask plate 323 allows the wall surfaces defining the holes 32H to have small areas, thereby reducing the volume of vapor deposition material adhering to the wall surfaces defining the holes 32H.

The second surface 322 includes second openings H2, which are openings of the holes 32H. The first surface 321 includes first openings H1, which are openings of the holes 32H. The second openings H2 are larger than the first openings H1 in a plan view. Each mask hole 32H is a passage for the vapor deposition particles sublimated from the vapor deposition source. The vapor deposition material sublimated from the vapor deposition source moves from the second openings H2 to the first openings H1. The second openings H2 that are larger than the first openings H1 increase the amount of vapor deposition material entering the holes 32H through the second openings H2. The area of each hole 32H in a cross-section taken along the first surface 321 may increase monotonically from the first opening H1 toward the second opening H2, or may be substantially uniform in a section between the first opening H1 and the second opening H2.

As shown in FIG. 6, another example of a mask portion 32 includes a plurality of holes 32H extending through the mask plate 323. The second openings H2 are larger than the first openings H1 in a plan view. Each hole 32H consists of a large hole 32LH, which includes a second opening H2, and a small hole 32SH, which includes a first opening H1. The large hole 32LH has a cross-sectional area that monotonically decreases from the second opening H2 toward the first surface 321. The small hole 32SH has a cross-sectional area that monotonically decreases from the first opening H1 toward the second surface 322. The section of the wall surface defining each hole 32H where the large hole 32LH meets the small hole 32SH at a middle section in the thickness direction of the mask plate 323 projects inward of the hole 32H. The distance between the first surface 321 and the protruding section of the wall surface defining the hole 32H is a step height SH. The example of cross-sectional structure shown in FIG. 5 has zero step height SH. To increase the amount of vapor deposition material reaching the first openings H1, the step height SH is preferably zero. In order for a mask portion 32 to have zero step height SH, the mask plate 323 should be thin enough so that wet etching from only one side of the vapor deposition mask substrate 1 achieves formation of holes 32H. For example, the mask plate 323 may have a thickness of less than or equal to 50 μm.

[Mask Portion Joining Structure]

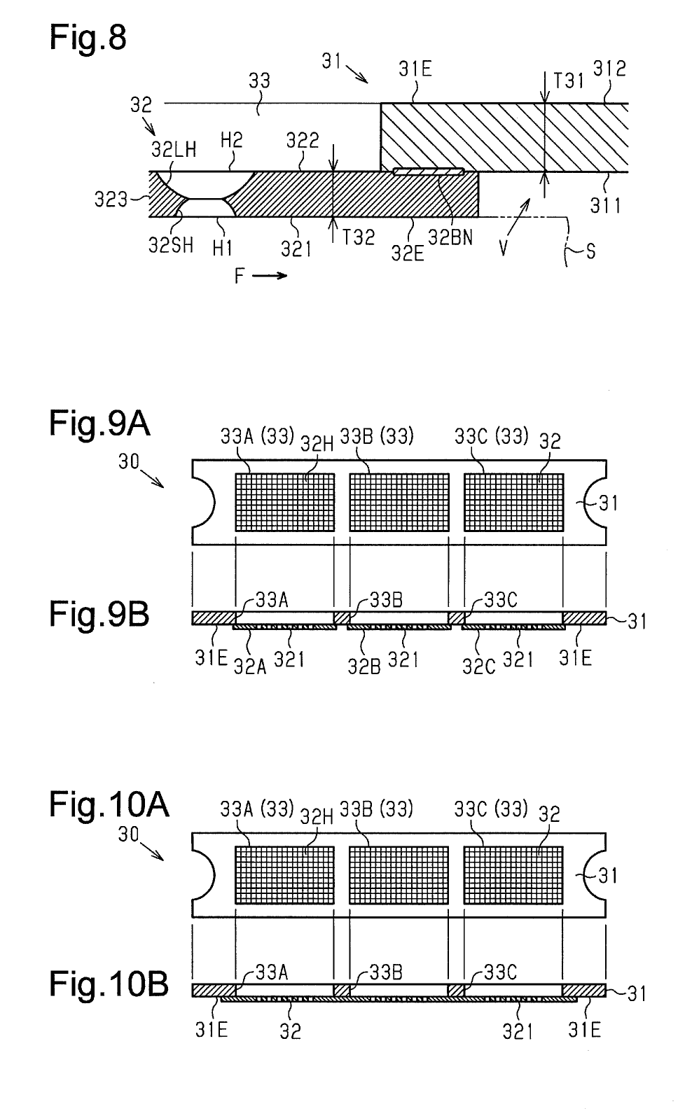

FIG. 7 shows an example of the cross-sectional structure of joining between a mask portion 32 and a frame portion 31. FIG. 8 shows another example of the cross-sectional structure of joining between a mask portion 32 and a frame portion 31.

In the example shown in FIG. 7, the outer edge section 32E of a mask plate 323 is a region that is free of holes 32H. The part of the second surface 322 of the mask plate 323 included in the outer edge section 32E of the mask plate 323 is an example of a side surface of the mask portion and joined to the frame portion 31. The frame portion 31 includes inner edge sections 31E defining frame holes 33. Each inner edge section 31E includes a joining surface 311 (the lower surface in FIG. 7), which faces the mask plate 323, and a non-joining surface 312 (the upper surface in FIG. 7), which is opposite to the joining surface 311. The thickness T31 of the inner edge section 31E, that is, the distance between the joining surface 311 and the non-joining surface 312 is sufficiently larger than the thickness T32 of the mask plate 323, allowing the frame portion 31 to have a higher rigidity than the mask plate 323. In particular, the frame portion 31 has a high rigidity that limits sagging of the inner edge section 31E by its own weight and displacement of the inner edge section 31E toward the mask portion 32. The joining surface 311 of the inner edge section 31E includes a joining section 32BN, which is joined to the second surface 322.

The joining section 32BN extends continuously or intermittently along substantially the entire circumference of the inner edge section 31E. The joining section 32BN may be a welding mark formed by welding the joining surface 311 to the second surface 322, or a joining layer joining the joining surface 311 to the second surface 322. When the joining surface 311 of the inner edge section 31E is joined to the second surface 322 of the mask plate 323, the frame portion 31 applies stress F to the mask plate 323 that pulls the mask plate 323 outward.

The main frame 20 also applies stress to the frame portion 31 that pulls the frame portion 31 outward. This stress corresponds to the stress F applied to the mask plate 323. Accordingly, the vapor deposition mask 30 removed from the main frame 20 is released from the stress caused by the joining between the main frame 20 and the frame portion 31, and the stress F applied to the mask plate 323 is relaxed. The position of the joining section 32BN in the joining surface 311 is preferably set such that the stress F isotropically acts on the mask plate 323. Such a position may be selected according to the shape of the mask plate 323 and the shape of the frame holes 33.

The joining surface 311 is a plane including the joining section 32BN and extends outward of the mask plate 323 from the outer edge section 32E of the second surface 322. In other words, the inner edge section 31E has a planar structure that virtually extends the second surface 322 outward, so that the inner edge section 31E extends from the outer edge section 32E of the second surface 322 toward the outside of the mask plate 323. Accordingly, in the area in which the joining surface 311 extends, a space V, which corresponds to the thickness of the mask plate 323, is likely to form around the mask plate 323. This limits physical interference between the vapor deposition target S and the frame portion 31 around the mask plate 323.

FIG. 8 shows another example in which the outer edge section 32E of the second surface 322 includes a region that is free of holes 32H. The outer edge section 32E of the second surface 322 includes a joining section 32BN with which the outer edge section 32E is joined to the joining surface 311 of the frame portion 31. The frame portion 31 applies stress F to the mask plate 323 that pulls the mask plate 323 outward. The frame portion 31 also creates a space V, which corresponds to the thickness of the mask plate 323, in the area where the joining surface 311 extends.

The mask plate 323 that is not subjected to the stress F may have some undulations in a similar manner as the vapor deposition mask substrate 1. The mask plate 323 that is subjected to the stress F, that is, the mask plate 323 mounted to the vapor deposition mask 30, may deform such that the heights of the undulations are reduced. However, any deformation caused by the stress F does not exceed the permissible degree when the vapor deposition mask substrate 1 satisfies the conditions described above. Accordingly, the holes 32H in the vapor deposition mask 30 are less likely to deform, improving the accuracy of the position and shape of the patterns.

[Quantity of Mask Portions]

FIGS. 9A and 9B show an example of the relationship between the quantity of holes 32H in a vapor deposition mask 30 and the quantity of holes 32H in a mask portion 32. FIGS. 10A and 10B show another example of the relationship between the quantity of holes 32H in a vapor deposition mask 30 and the quantity of holes 32H in a mask portion 32.

FIG. 9A shows an example in which the frame portion 31 includes three frame holes 33 (33A, 33B, and 33C). As shown in FIG. 9B, the vapor deposition mask 30 of this example includes one mask portion 32 (32A, 32B, or 32C) in each of the frame holes 33. The inner edge section 31E defining the frame hole 33A is joined to a mask portion 32A, the inner edge section 31E defining the frame hole 33B is joined to another mask portion 32B, and the inner edge section 31E defining the frame hole 33C is joined to the other mask portion 32C.

The vapor deposition mask 30 is used repeatedly for a plurality of vapor deposition targets. Thus, the position and structure of the holes 32H in the vapor deposition mask 30 need to be highly accurate. When the position and structure of the holes 32H fail to have the desired accuracy, the mask portions 32 may require replacement when manufacturing or repairing the vapor deposition mask 30.

When only one of the mask portions 32 needs to be replaced, for example, the structure in which the quantity of holes 32H required in one frame portion 31 is divided into three mask portions 32 as shown in FIGS. 9A and 9B only requires the replacement of one of the three mask portions 32. In other words, the two of the three mask portions 32 continue to be used. Thus, the structure in which the mask portions 32 are separately joined to the respective frame holes 33 reduces the consumption of various materials associated with the manufacturing and repair of the vapor deposition mask 30. In addition, a thinner mask plate 323 and smaller holes 32H tend to reduce the yield of the mask portion 32 and increase the need for replacement of the mask portion 32. Thus, the structure in which each frame hole 33 has one mask portion 32 is particularly suitable for a vapor deposition mask 30 that requires high resolution.

The position and structure of the holes 32H are preferably determined while the stress F is applied, that is, while the mask portions 32 are joined to the frame portion 31. In this respect, the joining section 32BN preferably extends partly and intermittently along the inner edge section 31E so that the mask portion 32 is replaceable.

FIG. 10A shows an example in which the frame portion 31 includes three frame holes 33 (33A, 33B, and 33C). As shown in the example of FIG. 10B, the vapor deposition mask 30 may include one mask portion 32, which is common to the frame holes 33. The inner edge section 31E defining the frame hole 33A, the inner edge section 31E defining the frame hole 33B, and the inner edge section 31E defining the frame hole 33C are joined to the common mask portion 32.

The structure in which the quantity of the holes 32H required in one frame portion 31 is assigned to a single mask portion 32 involves only one mask portion 32 joined to the frame portion 31. This reduces the load required for joining between the frame portion 31 and the mask portion 32. In addition, a thicker mask plate 323 forming the mask portion 32 and larger holes 32H tend to increase the yield of the mask portion 32 and reduce the need for replacement of the mask portion 32. Thus, the structure in which the frame holes 33 shares the common mask portion 32 is particularly suitable for a vapor deposition mask 30 that requires low resolution.

[Method for Manufacturing Vapor Deposition Mask Substrate]

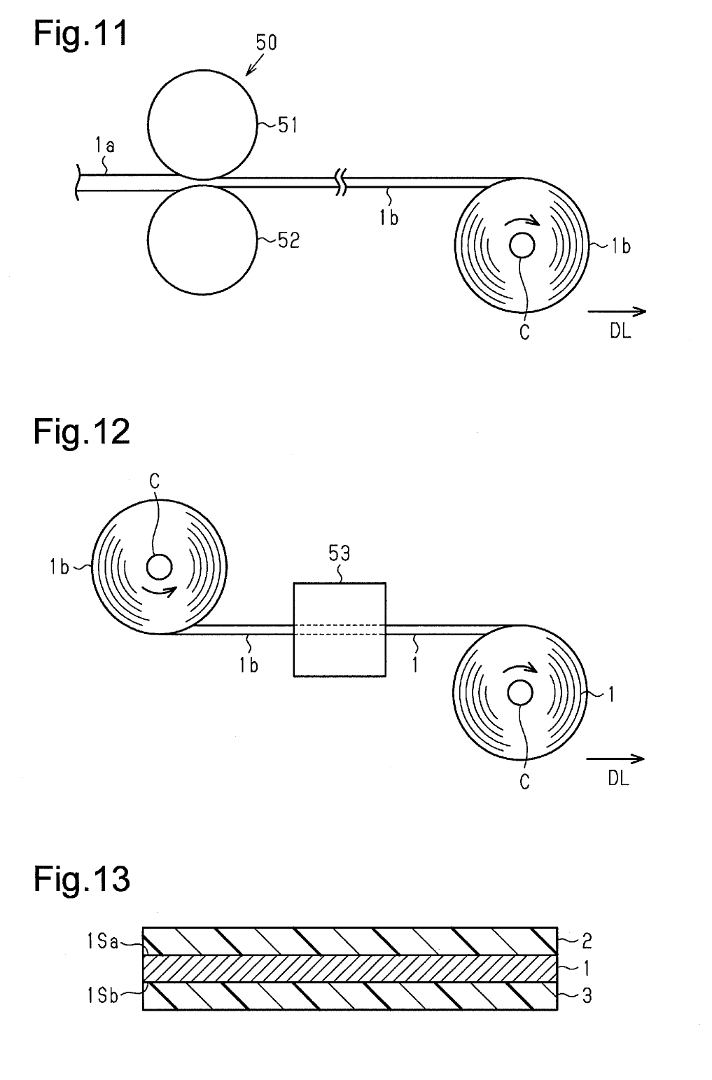

Methods for manufacturing the vapor deposition mask substrate are now described. As methods for manufacturing a vapor deposition mask substrate, a method using rolling and a method using electrolysis are described separately. The method using rolling is first described, followed by the method using electrolysis. FIGS. 11 and 12 show an example using rolling.

Referring to FIG. 11, the method using rolling first prepares a base material 1a made of Invar, for example. The base material 1a extends in the longitudinal direction DL. Then, the base material 1a is transferred toward a rolling mill 50 such that the longitudinal direction DL of the base material 1a is parallel to the direction in which the base material 1a is transferred. The rolling mill 50 may include a pair of rolls 51 and 52, which rolls the base material 1a. This stretches the base material 1a in the longitudinal direction DL, forming a rolled material 1b. The rolled material 1b is cut so as to have a width W in the width direction DW. The rolled material 1b may be wound around a core C or handled in a state of being extended in the shape of a strip. The rolled material 1b has a thickness of between 10 μm and 50 μm inclusive, for example. FIG. 12 shows an example in which a single pair of rolls is used, but a plurality of pairs of rolls may be used.

As shown in FIG. 12, the rolled material 1b is then transferred to an annealing apparatus 53. The annealing apparatus 53 heats the rolled material 1b that is being stretched in the longitudinal direction DL. This removes the residual stress remaining in the rolled material 1b and forms the vapor deposition mask substrate 1. The pressing force between the rolls 51 and 52, the rotation speed of the rolls 51 and 52, and the annealing temperature of the rolled material 1b are set to satisfy Condition 1. Preferably, parameters such as the pressing force between the rolls 51 and 52, the rotation speed of the rolls 51 and 52, the pressing temperature of the rolls 51 and 52, and the annealing temperature of the rolled material 1b are set to satisfy Conditions 2 to 4, in addition to Condition 1. The rolled material 1b may be cut after the annealing process so as to have the width W in the width direction DW.

In the method using electrolysis, the vapor deposition mask substrate 1 is formed on the surface of the electrode for electrolysis and then removed from the surface. This may use an electrolytic drum electrode, which has a mirror-finished surface and is immersed in the electrolytic bath, and another electrode, which supports the electrolytic drum electrode from the lower side and faces the surface of the electrolytic drum electrode. An electric current flows between the electrolytic drum electrode and the other electrode, and the vapor deposition mask substrate 1 is deposited on the electrode surface, which is the surface of the electrolytic drum electrode. When the vapor deposition mask substrate 1 on the rotating electrolysis drum electrode obtains the desired thickness, the vapor deposition mask substrate 1 is peeled off from the surface of the electrolysis drum electrode and wound into a roll.

When the vapor deposition mask substrate 1 is made of Invar, the electrolytic bath for electrolysis contains an iron ion source, a nickel ion source, and a pH buffer, for example. The electrolytic bath used for electrolysis may also contain a stress relief agent, an Fe³⁺ ion masking agent, and a complexing agent, such as malic acid and citric acid, and is a weakly acidic solution having a pH adjusted for electrolysis. Examples of the iron ion source include ferrous sulfate heptahydrate, ferrous chloride, and ferrous sulfamate. Examples of the nickel ion source include nickel (II) sulfate, nickel (II) chloride, nickel sulfamate, and nickel bromide. Examples of the pH buffer include boric acid and malonic acid. Malonic acid also functions as an Fe³⁺ ion masking agent. The stress relief agent may be saccharin sodium, for example. The electrolytic bath used for electrolysis may be an aqueous solution containing additives listed above and is adjusted using a pH adjusting agent, such as 5% sulfuric acid or nickel carbonate, to have a pH of between 2 and 3 inclusive, for example. If necessary, an annealing step may be included.

As the conditions for electrolysis, the temperature of the electrolytic bath, current density, and electrolysis time are adjusted according to the properties of the vapor deposition mask substrate 1, such as the thickness and composition ratio. The anode used in the electrolytic bath may be made of pure iron and nickel. The cathode used in the electrolytic bath may be a plate of stainless steel such as SUS304. The temperature of the electrolytic bath may be between 40° C. and 60° C. inclusive. The current density may be between 1 A/dm² and 4 A/dm² inclusive. The current density on the surface of the electrode is set to satisfy Condition 1. Preferably, the current density at the surface of the electrode is set to satisfy Conditions 2 to 4, in addition to Condition 1.

The vapor deposition mask substrate 1 produced by electrolysis and the vapor deposition mask substrate 1 produced by rolling may be further thinned by chemical or electrical polishing. The polishing solution used for chemical polishing may be a chemical polishing solution for an iron-based alloy that contains hydrogen peroxide as the main component. The electrolyte used for electrical polishing is a perchloric acid based electropolishing solution or a sulfuric acid based electropolishing solution. Since the conditions described above are satisfied, the surface of the vapor deposition mask substrate 1 has limited variation in the result of polishing using the polishing solution and the result of cleaning of the polishing solution using a cleaning solution.

[Method for Manufacturing Mask Portion]

Referring to FIGS. 13 to 18, a process for manufacturing the mask portion 32 shown in FIG. 6 is now described. The process for manufacturing the mask portion 32 shown in FIG. 5 is the same as the process for manufacturing the mask portion 32 shown in FIG. 6 except that the small holes 32SH are formed as through-holes and the step of forming large holes 32LH is omitted. The overlapping steps are not described.

Referring to FIG. 13, manufacturing of a mask portion starts with preparation of a vapor deposition mask substrate 1 including a first surface 1Sa and a second surface 1Sb, a first dry film resist 2 (a first DFR 2) to be affixed to the first surface 1Sa, and a second dry film resist 3 (a second DFR 3) to be affixed to the second surface 1Sb. The DFRs 2 and 3 are formed separately from the vapor deposition mask substrate 1. Then, the first DFR 2 is affixed to the first surface 1Sa, and the second DFR 3 is affixed to the second surface 1Sb. Since the conditions described above are satisfied, the affixation between the vapor deposition mask substrate 1, which is transferred in the longitudinal direction DL, and the DFRs 2 and 3, which are transferred along the vapor deposition mask substrate 1, is less likely to cause deviations in transfer, misalignment, or creases.

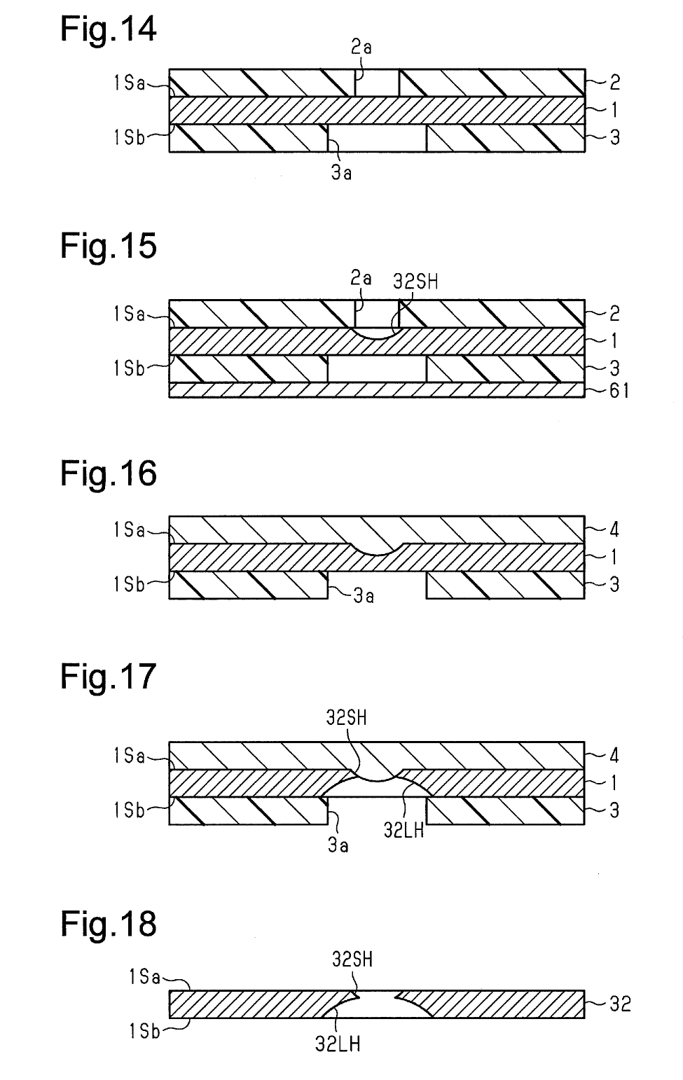

Referring to FIG. 14, the sections of the DFRs 2 and 3 other than the sections in which holes are to be formed are exposed to light, and then the DFRs are developed. This forms first through-holes 2a in the first DFR 2 and second through-holes 3a in the second DFR 3. The development of the exposed DFRs uses sodium carbonate solution, for example, as the developing solution. Since the conditions described above are satisfied, the surface of the vapor deposition mask substrate 1 has limited variation in the result of development using the developing solution and the result of cleaning using a cleaning solution. In addition, the process of affixing is unlikely to cause deviations in transfer, misalignment, or creases, thereby limiting associated displacement of the exposure position and increasing the exposure accuracy. This increases the uniformity of the shape and size of the first and second through-holes 2a and 3a in the surface of the vapor deposition mask substrate 1.

As shown in FIG. 15, the first surface 1Sa of the vapor deposition mask substrate 1 may be etched with ferric chloride solution using the developed first DFR 2 as the mask. Here, a second protection layer 61 is formed over the second surface 1Sb so that the second surface 1Sb is not etched together with the first surface 1Sa. The second protection layer 61 may be made of any material that chemically resists the ferric chloride solution. Small holes 32SH extending toward the second surface 1Sb are thus formed in the first surface 1Sa. Each small hole 32SH includes a first opening H1, which opens in the first surface 1Sa. Since the conditions described above are satisfied, the surface of the vapor deposition mask substrate 1 has limited variation in the result of etching using an etchant and the result of cleaning using a cleaning solution. This increases the uniformity of the shape and size of the small holes 32SH in the surface of the vapor deposition mask substrate 1.

The etchant for etching the vapor deposition mask substrate 1 may be an acidic etchant. When the vapor deposition mask substrate 1 is made of Invar, any etchant that is capable of etching Invar may be used. The acidic etchant may be a solution containing perchloric acid, hydrochloric acid, sulfuric acid, formic acid, or acetic acid mixed in a ferric perchlorate solution or a mixture of a ferric perchlorate solution and a ferric chloride solution. The vapor deposition mask substrate 1 may be etched by a dipping method that immerses the vapor deposition mask substrate 1 in an acidic etchant, or by a spraying method that sprays an acidic etchant onto the vapor deposition mask substrate 1.

Referring to FIG. 16, the first DFR 2 formed on the first surface 1Sa and the second protection layer 61 on the second DFR 3 are removed. In addition, a first protection layer 4 is formed on the first surface 1Sa to prevent additional etching of the first surface 1Sa. The first protection layer 4 may be made of any material that chemically resists the ferric chloride solution.

Then, as shown in FIG. 17, the second surface 1Sb is etched with ferric chloride solution using the developed second DFR 3 as the mask. Large holes 32LH extending toward the first surface 1Sa are thus formed in the second surface 1Sb. Each large hole 32LH has a second opening H2, which opens in the second surface 1Sb. The second openings H2 are larger than the first openings H1 in a plan view of the second surface 1Sb. Since the conditions described above are satisfied, the surface of the vapor deposition mask substrate 1 has limited variation in the result of etching using an etchant and the result of cleaning of the etchant using a cleaning solution. This increases the uniformity of the shape and size of the large holes 32LH in the surface of the vapor deposition mask substrate 1. The etchant used in this step may also be an acidic etchant. When the vapor deposition mask substrate 1 is made of Invar, any etchant that is capable of etching Invar may be used. The vapor deposition mask substrate 1 may also be etched by a dipping method that immerses the vapor deposition mask substrate 1 in an acidic etchant, or by a spraying method that sprays an acidic etchant onto the vapor deposition mask substrate 1.

As shown in FIG. 18, removing the first protection layer 4 and the second DFR 3 from the vapor deposition mask substrate 1 provides the mask portion 32 having a plurality of small holes 32SH and large holes 32LH connected to the small holes 32SH.

In the manufacturing method using rolling, the vapor deposition mask substrate 1 includes some amount of a metallic oxide, such as an aluminum oxide or a magnesium oxide. That is, when the base material 1a is formed, a deoxidizer, such as granular aluminum or magnesium, is typically mixed into the material to limit mixing of oxygen into the base material 1a. The aluminum or magnesium remains to some extent in the base material 1a as a metallic oxide such as an aluminum oxide or a magnesium oxide. In this respect, the manufacturing method using electrolysis limits mixing of the metallic oxide into the mask portion 32.

[Method for Manufacturing Vapor Deposition Mask]

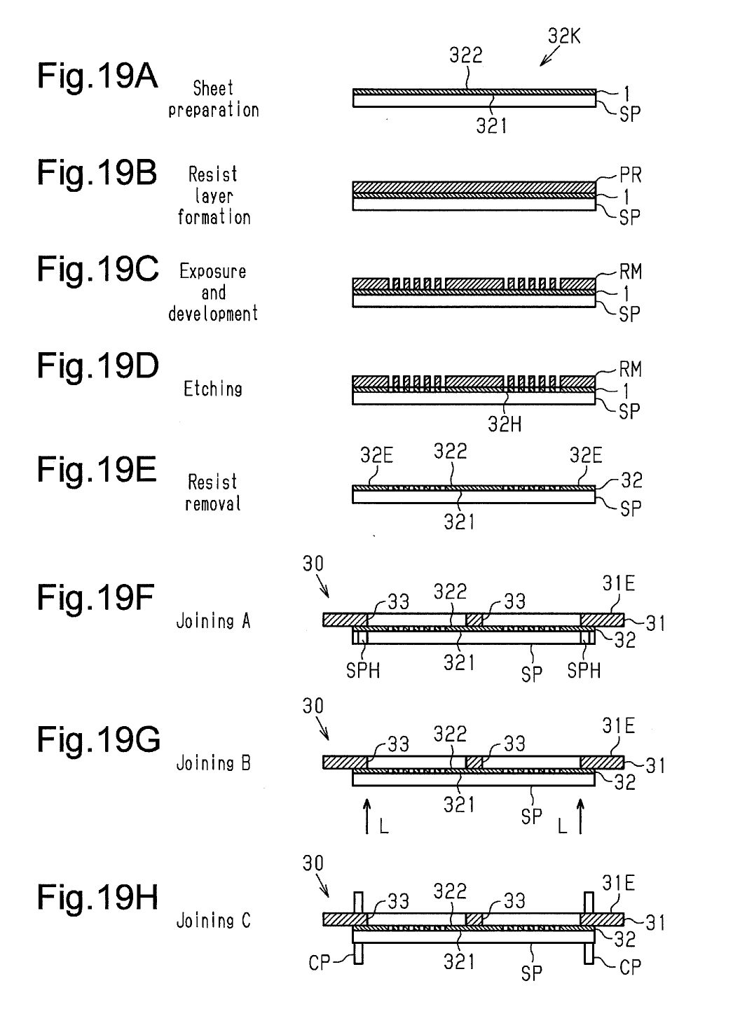

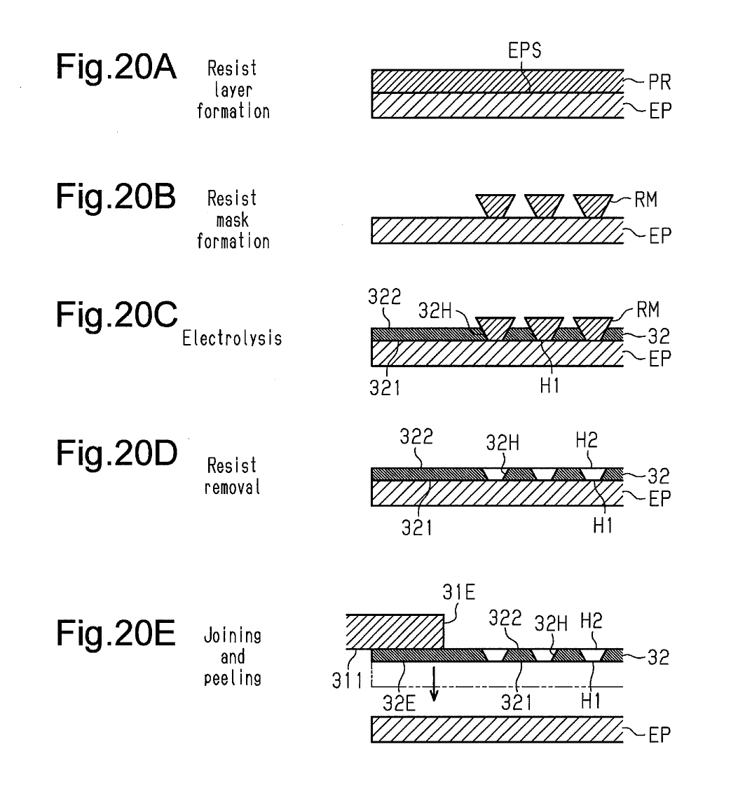

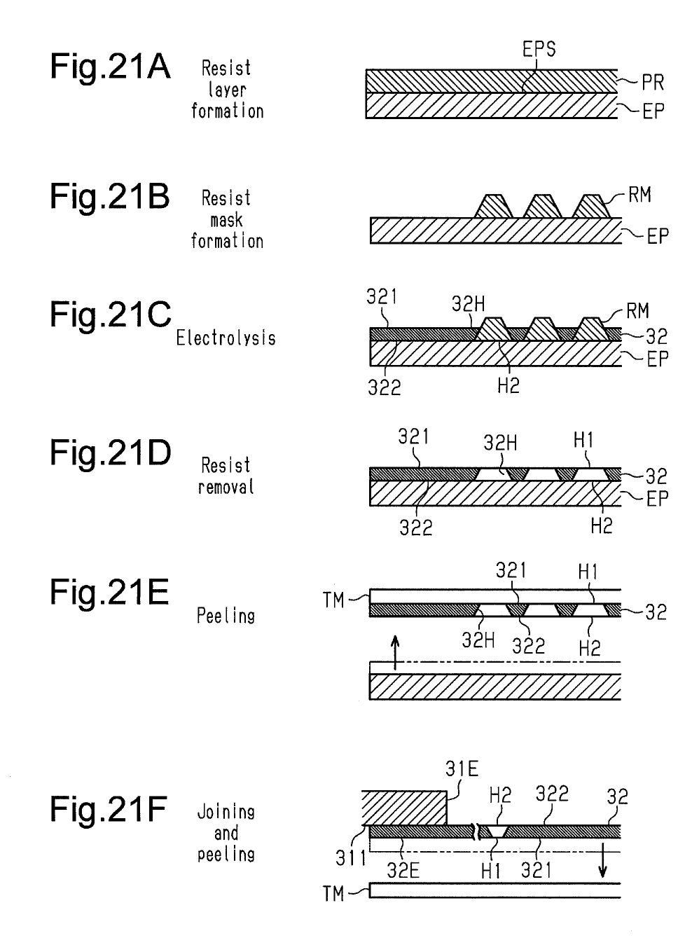

Various examples of a method for manufacturing a vapor deposition mask are now described. Referring to FIGS. 19A to 19H, an example of a method for forming holes by wet etching (the first manufacturing method) is described. Referring to FIGS. 20A to 20E, an example of a method for forming holes by electrolysis (the second manufacturing method) is described. Referring to FIGS. 21A to 21F, another example of a method for forming holes by electrolysis (the third manufacturing method) is described.

[First Manufacturing Method]

The method for manufacturing a vapor deposition mask including the mask portion 32 described with reference to FIG. 5 and the method for manufacturing a vapor deposition mask including the mask portion 32 described with reference to FIG. 6 involve substantially identical processes except for the step of etching a substrate 32K. The following description mainly focuses on the method for manufacturing a vapor deposition mask including the mask portion 32 shown in FIG. 5. The overlapping steps in the method for manufacturing a vapor deposition mask including the mask portion 32 shown in FIG. 6 are not described.

In the example of a method for manufacturing a vapor deposition mask shown in FIGS. 19A to 19H, a substrate 32K is first prepared (FIG. 19A). The substrate 32K is the vapor deposition mask substrate 1 to be processed as the mask plate 323 and preferably includes, in addition to the vapor deposition mask substrate 1, a support SP, which supports the vapor deposition mask substrate 1. The first surface 321 of the substrate 32K (the lower surface in FIGS. 19A to 19H) corresponds to the first surface 1Sa described above, and the second surface 322 of the substrate 32K (the upper surface in FIGS. 19A to 19H) corresponds to the second surface 1Sb described above.

A resist layer PR is formed on the second surface 322 of the prepared substrate 32K (FIG. 19B), and the resist layer PR undergoes exposure and development so that a resist mask RM is formed on the second surface 322 (FIG. 19C). Holes 32H are then formed in the substrate 32K by wet etching from the second surface 322 using the resist mask RM (FIG. 19D).

In this step, second openings H2 are formed in the second surface 322, where the wet etching starts, and first openings H1 smaller than the second openings H2 are formed in the first surface 321, which is subjected to the wet etching after the second surface 322. The resist mask RM is then removed from the second surface 322, leaving the mask portion 32 described above (FIG. 19E). Finally, the outer edge sections 32E of the second surface 322 are joined to the inner edge sections 31E of a frame portion 31, and the support SP is removed from the mask portion 32 to complete the vapor deposition mask 30 (FIGS. 19F to 19H).

In the method for manufacturing a vapor deposition mask including the mask portion 32 shown in FIG. 6, the steps described above are performed on the surface of a substrate 32K corresponding to the first surface 321 to form small holes 32SH. This substrate 32K does not include a support SP. The small holes 32SH are then filled with a material for protecting the small holes 32SH, such as a resist. Then, the steps described above are performed on the surface of the substrate 32K corresponding to the second surface 322, thereby forming a mask portion 32.

The example shown in FIG. 19F uses resistance welding to join the outer edge sections 32E of the second surface 322 to the inner edge sections 31E of the frame portion 31. This method forms a plurality of holes SPH in an insulative support SP. The holes SPH are formed in the sections of the support SP that face the sections that become joining sections 32BN. Then, the joining sections 32BN are formed separately by energization through the holes SPH. This welds the outer edge sections 32E to the inner edge sections 31E.

The example shown in FIG. 19G uses laser welding to join the outer edge sections 32E of the second surface 322 to the inner edge sections 31E of the frame portion 31. This method uses a light transmitting support SP and irradiates the sections that become joining sections 32BN with laser light L through the support SP. Separate joining sections 32BN are formed by intermittently applying laser light L around the outer edge section 32E. Alternatively, a continuous joining section 32BN is formed along the entire circumference of the outer edge section 32E by continuously applying laser light L around the outer edge sections 32E. This welds the outer edge sections 32E to the inner edge sections 31E.

The example shown in FIG. 19H uses ultrasonic welding to join the outer edge sections 32E of the second surface 322 to the inner edge sections 31E of the frame portion 31. This method applies ultrasonic waves to the sections that become joining sections 32BN with the outer edge sections 32E and the inner edge sections 31E held together by clamps CP or other device. The member to which ultrasonic waves are directly applied may be the frame portion 31 or the mask portion 32. The method using ultrasonic welding leaves crimp marks of the clamps CP in the frame portion 31 and the support SP.

In the joining process described above, fusing or welding may be performed while stress is acting on the mask portion 32 outward of the mask portion 32. When the support SP supports the mask portion 32 while stress is acting on the mask portion 32 outward of the mask portion 32, the application of stress to the mask portion 32 may be omitted.

[Second Manufacturing Method]

In addition to the first manufacturing method, the vapor deposition masks described with reference to FIGS. 7 and 8 may be manufactured by another example shown in FIGS. 20A to 20E.

The example shown in FIGS. 20A to 20E first forms a resist layer PR on an electrode surface EPS, which is a surface of an electrode EP used for electrolysis (see FIG. 20A). Then, the resist layer PR undergoes exposure and development so that a resist mask RM is formed on the electrode surface EPS (see FIG. 20B). The resist mask RM includes the shape of a reverse truncated cone in a cross-section perpendicular to the electrode surface EPS. The cross-sectional area of each shape along the electrode surface EPS increases away from the electrode surface EPS. Then, electrolysis is performed using the electrode surface EPS having the resist mask RM, and a mask portion 32 is formed over the region on the electrode surface EPS other than the resist mask RM (FIG. 20C).

In this step, the mask portion 32 is formed in the space that is not occupied by the resist mask RM. Accordingly, the mask portion 32 includes holes shaped corresponding to the shape of the resist mask RM. Self-aligned holes 32H are thus formed in the mask portion 32. The surface in contact with the electrode surface EPS functions as the first surface 321 having the first openings H1, and the outermost surface having second openings H2, which are larger than the first openings H1, functions as the second surface 322.

Then, only the resist mask RM is removed from the electrode surface EPS, leaving holes 32H, which are hollows extending from the first openings H1 to the second openings H2 (see FIG. 20D). Finally, the joining surface 311 of the inner edge section 31E is joined to the outer edge section 32E of the second surface 322 including second openings H2, and then stress is applied to the frame portion 31 to peel off the mask portion 32 from the electrode surface EPS. The vapor deposition mask 30 in which the mask portion 32 is joined to the frame portion 31 is thus manufactured (FIG. 20E).

In the second manufacturing method, the mask portion 32 is formed without etching the vapor deposition mask substrate 1. When the outer edge section 32E satisfies Condition 1, with the direction along one side of the mask portion 32 being the width direction, the positional accuracy in the joining between the frame portion 31 and the mask portion 32 and the strength of the joining are increased.

[Third Manufacturing Method]

In addition to the first manufacturing method, the vapor deposition masks described with reference to FIGS. 7 and 8 may be manufactured by another example shown in FIGS. 21A to 21F.

The example shown in FIGS. 21A to 21F first forms a resist layer PR on an electrode surface EPS, which is used for electrolysis (see FIG. 21A). Then, the resist layer PR undergoes exposure and development so that a resist mask RM is formed on the electrode surface EPS (see FIG. 21B). The resist mask RM includes the shape of a truncated cone in a cross-section perpendicular to the electrode surface EPS. The cross-sectional area of each shape along the electrode surface EPS decreases away from the electrode surface EPS. Then, electrolysis is performed using the electrode surface EPS having the resist mask RM, and a mask portion 32 is formed over the region on the electrode surface EPS other than the resist mask RM (FIG. 21C).

In this step, the mask portion 32 is formed in the space that is not occupied by the resist mask RM. Accordingly, the mask portion 32 includes holes shaped corresponding to the shape of the resist mask RM. Self-aligned holes 32H are thus formed in the mask portion 32. The surface in contact with the electrode surface EPS functions as the second surface 322 having the second openings H2, and the outermost surface having the first openings H1, which are smaller than the second openings H2, functions as the first surface 321.

Then, only the resist mask RM is removed from the electrode surface EPS, leaving holes 32H, which are hollows extending from the first openings H1 to the second openings H2 (see FIG. 21D). An intermediate transfer substrate TM is joined to the first surface 321 including the first openings H1, and stress is then applied to the intermediate transfer substrate TM to peel off the mask portion 32 from the electrode surface EPS. This separates the second surface 322 from the electrode surface EPS with the mask portion 32 joined to the intermediate transfer substrate TM (FIG. 21E). Finally, the joining surface 311 of the inner edge section 31E is joined to the outer edge section 32E of the second surface 322, and then the intermediate transfer substrate TM is removed from the mask portion 32. The vapor deposition mask 30 in which the mask portion 32 is joined to the frame portion 31 is thus manufactured (FIG. 21F).

In the third manufacturing method, the mask portion 32 is formed without etching the vapor deposition mask substrate material 1. When the outer edge section 32E satisfies Condition 1, with the direction along one side of the mask portion 32 being the width direction, the positional accuracy in the joining between the frame portion 31 and the mask portion 32 and the strength of the joining are increased.

In the method for manufacturing a display device using the vapor deposition mask 30 described above, the mask device 10 to which the vapor deposition mask 30 is mounted is set in the vacuum chamber of the vapor deposition apparatus. The mask device 10 is attached such that the first surface 321 faces the vapor deposition target, such as a glass substrate, and the second surface 322 faces the vapor deposition source. Then, the vapor deposition target is transferred into the vacuum chamber of the vapor deposition apparatus, and the vapor deposition material is sublimated from the vapor deposition source. This forms a pattern that is shaped corresponding to the first opening H1 on the vapor deposition target, which faces the first opening H1. The vapor deposition material may be an organic light-emitting material for forming pixels of a display device, or a pixel electrode for forming a pixel circuit of a display device, for example.

### EXAMPLES

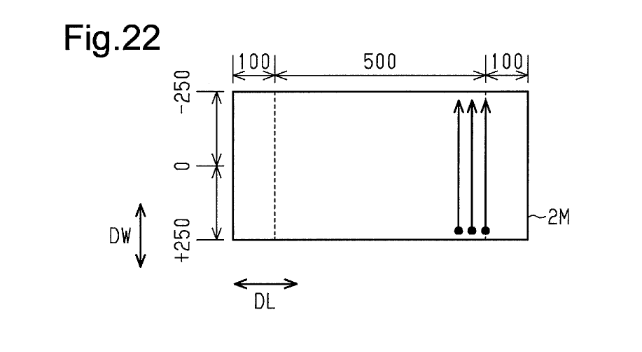

Referring to FIG. 22, Examples are now described.

A base material 1a, which was made of Invar, was subjected to a rolling step to form a metal sheet. The metal sheet was subjected to a slitting step of cutting the metal sheet into sections of the desired dimension in the width direction DW to form a rolled material 1b. The rolled material 1b was annealed to form a vapor deposition mask substrate 1 of Example 1, which had a length in the width direction DW of 500 mm and a thickness of 20 μm.

Also, a vapor deposition mask substrate 1 of Example 2 having a length in the width direction DW of 500 mm and a thickness of 20 μm was obtained under the same conditions as Example 1 except that the rotation speed and pressing force of the rolls 51 and 52 were changed from those in Example 1.

The vapor deposition mask substrate 1 of Example 3 having a length in the width direction DW of 500 mm and a thickness of 50 μm was obtained under the same conditions as Example 1 except that the pressing force between the rolls 51 and 52 was changed from that in Example 1.

Further, a vapor deposition mask substrate 1 of Example 4 having a length in the width direction DW of 500 mm and a thickness of 20 μm was obtained under the same conditions as Example 1 except that the number of rolls 51 and 52 was changed from that in Example 1.

Subsequently, a vapor deposition mask substrate 1 of Comparison Example 1 having a length in the width direction DW of 500 mm and a thickness of 20 μm was obtained under the same conditions as Example 1 except that the number and temperature of the rolls 51 and 52 were changed from those in Examples 1 and 4.

Also, a vapor deposition mask substrate 1 of Comparison Example 2 having a length in the width direction DW of 500 mm and a thickness of 20 μm was obtained under the same conditions as Example 1 except that the number and the pressing force of rolls 51 and 52 were changed from those in Examples 1 and 3.

Further, a vapor deposition mask substrate 1 of Comparison Example 3 having a length in the width direction DW of 500 mm and a thickness of 20 μm was obtained under the same conditions as Example 1 except that the number and the pressing force of rolls 51 and 52 were changed from those in Example 1.

Referring to FIG. 22, a measurement substrate 2M having a length in the longitudinal direction DL of 700 mm was cut out from the vapor deposition mask substrate 1 of each of Examples and Comparison Examples. Then, the steepnesses in the width direction DW of each of the obtained measurement substrates 2M were measured over the entire measurement area ZL. The measurement conditions of steepnesses in the width direction DW were as follows.

Measurement device: CNC image measurement system VMR-6555 manufactured by Nikon Corporation

Length in the longitudinal direction DL of measurement area ZL: 500 mm (unit length)

Length in the longitudinal direction DL of non-measurement area ZE: 100 mm

Measurement interval in the longitudinal direction DL: 20 mm

Measurement interval in the width direction DW: 20 mm

To exclude the undulated shape added in the slitting step, measurement in the width direction was performed for the area of 480 mm in the width direction DW, excluding the areas of 10 mm from the edges in the width direction DW. Specifically, measurement was performed at 25 points along the width direction DW on each of 26 lines arranged in the longitudinal direction DL. With any of the measurement intervals in each of Examples and Comparison Examples, the longitudinal direction DL is the direction in which the base material 1a is stretched by rolling.

Table 1 shows the measurement results of the first steepness, the average value of second steepnesses, the maximum value of undulation quantities, and the average value of undulation quantities of each of Examples 1 to 4 and Comparison Examples 1 to 3.

Table 1 shows that the first steepness of Example 1 was 0.43%, indicating that Example 1 satisfied Condition 1. Of the twenty-six lines in Example 1, four lines each had a minimum value of unit steepnesses of 0% and were free of a noticeable undulation in the width direction DW. The average value of the second steepnesses in Example 1 was 0.20%, satisfying Condition 2. The standard deviation σ of the second steepnesses was 0.12%. The maximum value of the undulation quantities in Example 1 was four, satisfying Condition 3. Further, the average value of the undulation quantities in Example 1 was one, satisfying Condition 4.

Example 2 had a first steepness of 0.29%, satisfying Condition 1. Of the twenty-six lines in Example 2, five lines each had a minimum value of unit steepnesses of 0% and were free of a noticeable undulation in the width direction DW. The average value of the second steepnesses in Example 2 was 0.12%, satisfying Condition 2. The standard deviation σ of the second steepnesses was 0.09%. The maximum value of the undulation quantities in Example 2 was three, satisfying Condition 3. Further, the average value of the undulation quantities in Example 2 was one, satisfying Condition 4.

Example 3 had a first steepness of 0.37%, satisfying Condition 1. Of the twenty-six lines in Example 3, seven lines each had a minimum value of unit steepnesses of 0% and were free of a noticeable undulation in the width direction DW. The average value of the second steepnesses in Example 3 was 0.11%, satisfying Condition 2. The standard deviation σ of the second steepnesses was 0.12%. The maximum value of the undulation quantities in Example 3 was three, satisfying Condition 3. Further, the average value of the undulation quantities in Example 3 was one, satisfying Condition 4.

Example 4 had a first steepness of 0.44%, satisfying Condition 1. Of the twenty-six lines in Example 4, one line had a minimum value of unit steepnesses of 0% and was free of a noticeable undulation in the width direction DW. The average value of the second steepnesses in Example 4 was 0.22%, satisfying Condition 2. The standard deviation σ of the second steepnesses was 0.11%. The maximum value of the undulation quantities in Example 4 was five, failing to satisfy Condition 3. Further, the average value of the undulation quantities in Example 4 was two, satisfying Condition 4.

Comparison Example 1 had a first steepness of 0.90%, failing to satisfy Condition 1. The minimum value of the unit steepnesses in comparison Example 1 was 0.11%. The average value of the second steepnesses in Comparison Example 1 was 0.33%, failing to satisfy Condition 2. The standard deviation σ of the second steepnesses was 0.18%. The maximum value of the undulation quantities in Comparison Example 1 was eight, failing to satisfy Condition 3. Further, the average value of the undulation quantities in Comparison Example 1 was five, failing to satisfy Condition 4. The minimum value of the undulation quantities in Comparison Example 1 was three.

Comparison Example 2 had a first steepness of 1.39%, failing to satisfy Condition 1. The minimum value of the unit steepnesses in Comparison Example 2 was 0.06%. The average value of the second steepnesses in Comparison Example 2 was 0.28%, failing to satisfy Condition 2. The standard deviation σ of the second steepnesses was 0.29%. The maximum value of the undulation quantities in Comparison Example 2 was five, failing to satisfy Condition 3. Further, the average value of the undulation quantities in Comparison Example 2 was two, satisfying Condition 4. The minimum value of the undulation quantities in Comparison Example 2 was one.

Comparison Example 3 had a first steepness of 0.58%, failing to satisfy Condition 1. The minimum value of the unit steepnesses in Comparison Example 3 was 0.06%. The average value of the second steepnesses in Comparison Example 3 was 0.31%, failing to satisfy Condition 2. The standard deviation σ of the second steepnesses was 0.14%. The maximum value of the undulation quantities in Comparison Example 3 was six, failing to satisfy Condition 3. Further, the average value of the undulation quantities in Comparison Example 3 was four, failing to satisfy Condition 4. The minimum value of the undulation quantities in Comparison Example 3 was one.

TABLE 1

| | | | | | Comparison | Comparison | Comparison |
|---|---|---|---|---|---|---|---|
| | Example 1 | Example 2 | Example 3 | Example 4 | Example 1 | Example 2 | Example 3 |
| First | 0.43 | 0.29 | 0.37 | 0.44 | 0.90 | 1.39 | 0.58 |
| steepness | | | | | | | |
| (%) | | | | | | | |
| Average | 0.20 | 0.12 | 0.11 | 0.22 | 0.33 | 0.28 | 0.31 |
| value of | | | | | | | |
| second | | | | | | | |
| steepnesses | | | | | | | |
| (%) | | | | | | | |
| Maximum | 4 | 3 | 3 | 5 | 8 | 5 | 6 |
| value of | | | | | | | |
| undulation | | | | | | | |
| quantities | | | | | | | |
| (quantity) | | | | | | | |
| Average | 1 | 1 | 1 | 2 | 5 | 2 | 4 |
| value of | | | | | | | |
| undulation | | | | | | | |
| quantities | | | | | | | |
| (quantity) | | | | | | | |
| Variation | ◯ | ◯ | ◯ | ◯ | X | X | X |

[Pattern Accuracy]

A first DFR 2 having a thickness of 10 μm was affixed to the first surface 1Sa of the vapor deposition mask substrate 1 of each of Examples 1 to 4 and Comparison Examples 1 to 3. Each first DFR 2 underwent an exposure step, in which the first DFR 2 was exposed to light while in contact with an exposure mask, and a development step. This formed through-holes 2a having a diameter of 30 μm in the first DFR 2 in a grid pattern. Then, the first surface 1Sa was etched using the first DFR 2 as the mask so that holes 32H were formed in the vapor deposition mask substrate 1 in a grid pattern. The diameter of the opening of each hole 32H was measured in the width direction DW of the vapor deposition mask substrate 1. Table 1 shows the variations in diameter of the openings of the holes 32H in the width direction DW. In Table 1, the levels in which the difference between the maximum value and the minimum value of opening diameters of the holes 32H is less than or equal to 2.0 μm are marked with “o”, and the levels in which the difference between the maximum value and the minimum value of opening diameters is greater than 2.0 μm are marked with “×”.

As shown in Table 1, the variations in diameter of the openings of Examples 1 to 4 were less than or equal to 2.0 μm. Of Examples 1 to 4, Examples 1 to 3 had smaller variations in diameter of the openings than that of Example 4. Further, the variations in diameter of the openings of Comparison Examples 1 to 3 were greater than 2.0 μm. The comparison between Examples 1 to 4 and Comparison Examples 1 to 3 shows that a structure in which the first steepness is less than or equal to 0.5%, that is, a structure that satisfies Condition 1, limits variation in diameter of openings. In addition, a structure in which the average value of second steepnesses is less than or equal to 0.25%, that is, a structure that satisfies Condition 2, limits variation in diameter of openings.

The comparison between Examples 1 to 3 and Example 4 shows that a structure in which the undulation quantities per unit length are less than or equal to four, that is, a structure that satisfies Condition 3, further limits variations in diameter of openings. In addition, a structure in which the average value of the undulation quantities per unit length is less than or equal to two, that is, a structure that satisfies Condition 4, further limits variation in diameter of openings.

The above-described embodiment has the following advantages.

(1) The increased accuracy of the shape and size of the holes in the mask portion 32 increases the accuracy of the pattern formed by vapor deposition. The method for exposing the resist is not limited to a method of bringing the exposure mask into contact with the resist. The exposure may be performed without bringing the resist into contact with the exposure mask. Bringing the resist into contact with the exposure mask presses the vapor deposition mask substrate onto the surface of the exposure mask. This limits reduction in the accuracy of exposure, which would otherwise occur due to the undulated shape of the vapor deposition mask substrate. The accuracy in the step of processing the surface with liquid is increased regardless of the exposure method, thereby increasing the accuracy of the pattern formed by vapor deposition.

(2) The surface of the vapor deposition mask substrate 1 has limited variation in the result of development using a developing solution and the result of cleaning using a cleaning solution. This increases the uniformity of the shape and size of the first and second through-holes 2a and 3a, which are formed by the exposure step and the development step, in the surface of the vapor deposition mask substrate 1.

(3) The surface of the vapor deposition mask substrate 1 has limited variation in the result of etching using an etchant and the result of cleaning of the etchant using a cleaning solution. The surface of the vapor deposition mask substrate 1 has limited variation in the result of stripping of the resist layer using a stripping solution and the result of cleaning of the stripping solution using a cleaning solution. This increases the uniformity of the shape and size of the small holes 32SH and the large holes 32LH in the surface of the vapor deposition mask substrate 1.

(4) The quantity of holes 32H required in one frame portion 31 is divided into three mask portions 32. That is, the total area of the mask portions 32 required in one frame portion 31 is divided into three mask portions 32, for example. Thus, any partial deformation of a mask portion 32 in a frame portion 31 does not require replacement of all mask portions 32 in the frame portion 31. As compared with a structure in which one frame portion 31 includes only one mask portion 32, the size of a new mask portion 32 for replacing the deformed mask portion 32 may be reduced to about one-third.

(5) The steepnesses of each measurement substrate 2M are measured with the sections at the two edges in the longitudinal direction DL of the measurement substrate 2M and the sections at the two edges in the width direction DW of the measurement substrate 2M excluded as non-measurement areas from the measurement target of steepnesses. Each non-measurement area is the area that can have an undulated shape that is formed when the vapor deposition mask substrate 1 is cut and is thus differs from the undulated shape of the other section of the vapor deposition mask substrate 1. As such, excluding the non-measurement area ZE from the measurement target will increase the accuracy of measurement of steepnesses.

The above-described embodiment may be modified as follows.

[Method for Manufacturing a Vapor Deposition Mask Substrate]

In the rolling step, a rolling mill may be used that includes a plurality of pairs of rolls, which rolls the base material 1a. The method using a plurality of pairs of rolls increases the flexibility in terms of the control parameters for satisfying Conditions 1 to 3.

Further, instead of annealing the rolled material 1b while extending it in the longitudinal direction DL, the rolled material 1b may be annealed in a state of being wound around the core C in a roll. When the annealing is performed on the rolled material 1b wound in a roll, the vapor deposition mask substrate 1 may have the tendency for warpage according to the diameter of the roll. Thus, depending on the material of the vapor deposition mask substrate 1 and the diameter of the roll wound around the core C, it may be preferable that the rolled material 1b be annealed while extended.

Further, the rolling step and the annealing step may be repeated and alternate to produce a vapor deposition mask substrate 1.

The vapor deposition mask substrate 1 produced by electrolysis and the vapor deposition mask substrate 1 produced by rolling may be further thinned by chemical or electrical polishing. The conditions such as the composition and the supplying method of the polishing solution may be set so as to satisfy Conditions 1 to 3 after polishing. To relax the internal stress, the polished vapor deposition mask substrate 1 may be subjected to an annealing step.

Although the multiple embodiments have been described herein, it will be clear to those skilled in the art that the present invention may be embodied in different specific forms without departing from the spirit of the invention. The invention is not to be limited to the details given herein, but may be modified within the scope and equivalence of the appended claims.

1. A vapor deposition mask substrate, which is a metal sheet that has a shape of a strip and is configured to be etched to include a plurality of holes and used to manufacture a vapor deposition mask, wherein
the metal sheet has a longitudinal direction and a width direction,
the metal sheet has shapes in the width direction that are taken at different positions in the longitudinal direction of the metal sheet and differ from one another,
each shape includes undulations repeating in the width direction,
each undulation includes a valley at each of two ends of the undulation,
each undulation has a length, which is a length of a straight line in the width direction that connects one of the valleys of the undulation to the other valley,
a percentage of a height of each undulation relative to the length of the undulation is a unit steepness,
the metal sheet has a unit length in the longitudinal direction of 500 mm,
a maximum value of the unit steepnesses of the metal sheet per the unit length is a first steepness, and the first steepness is less than or equal to 0.5%.

2. The vapor deposition mask substrate according to claim 1, wherein
a maximum value of the unit steepnesses of all undulations in the width direction at each position in the longitudinal direction is a second steepness, and
an average value of the second steepnesses of the metal sheet per unit length is less than or equal to 0.25%.

3. The vapor deposition mask substrate according to claim 1, wherein
a number of undulations in the width direction at each position in the longitudinal direction is an undulation quantity at the position, and
a maximum value of the undulation quantities of the metal sheet per the unit length is less than or equal to four.

4. The vapor deposition mask substrate according to claim 1, wherein
a number of undulations in the width direction at each position in the longitudinal direction is an undulation quantity at the position, and
an average value of the undulation quantities of the metal sheet per the unit length is less than or equal to two.

5. A method for manufacturing a vapor deposition mask substrate, which is a metal sheet that has a shape of a strip and is configured to be etched to include a plurality of holes and used to manufacture a vapor deposition mask, the method comprising:
obtaining the metal sheet by rolling a base material, wherein
the metal sheet has a longitudinal direction and a width direction,
the metal sheet has shapes in the width direction that are taken at different positions in the longitudinal direction of the metal sheet and differ from one another,
each shape includes undulations repeating in the width direction,
each undulation includes a valley at each of two ends of the undulation,
each undulation has a length, which is a length of a straight line in the width direction that connects one of the valleys of the undulation to the other valley,
a percentage of a height of each undulation relative to the length of the undulation is a unit steepness,
the metal sheet has a unit length in the longitudinal direction of 500 mm,
a maximum value of the unit steepnesses of the metal sheet per the unit length is a first steepness, and
the base material is rolled such that the first steepness is less than or equal to 0.5%.

6. A method for manufacturing a vapor deposition mask, the method comprising:
forming a resist layer on a metal sheet having a shape of a strip; and
forming a plurality of holes in the metal sheet by etching using the resist layer as a mask to form a mask portion, wherein
the metal sheet has a longitudinal direction and a width direction,
the metal sheet has shapes in the width direction that are taken at different positions in the longitudinal direction of the metal sheet and differ from one another,
each shape includes undulations repeating in the width direction,
each undulation includes a valley at each of two ends of the undulation,
each undulation has a length, which is a length of a straight line in the width direction that connects one of the valleys of the undulation to the other valley,
a percentage of a height of each undulation relative to the length of the undulation is a unit steepness,
the metal sheet has a unit length in the longitudinal direction of 500 mm,
a maximum value of the unit steepnesses of the metal sheet per the unit length is a first steepness, and
the first steepness is less than or equal to 0.5%.

7. The method for manufacturing a vapor deposition mask according to claim 6, wherein
the mask portion is one of a plurality of mask portions,
forming the mask portion includes forming the mask portions in the single metal sheet,
the mask portions each include a separate side surface including some of the holes, and
the method further comprises joining the side surfaces of the mask portions to a single frame portion such that the single frame portion surrounds the holes of each mask portion.

8. A method for manufacturing a display device, the method comprising:
preparing a vapor deposition mask manufactured by the method for manufacturing a vapor deposition mask according to claim 6; and
forming a pattern by vapor deposition using the vapor deposition mask.
